(19) United States
(12) Patent Application Publication
(10) Pub. No.: US 2007/0269916 A1
(43) Pub. Date: Nov. 22, 2007

(54) ORGANIC LIGHT EMITTING DIODE DISPLAY AND MANUFACTURING METHOD

(76) Inventors: Tae-Whan KIM, Seoul (KR); Young-Bae Yoon, Gunsan-si (KR)

Correspondence Address: MACPHERSON KWOK CHEN & HEID LLP, 2033 GATEWAY PLACE, SUITE 400, SAN JOSE, CA, 95110, US

(21) Appl. No.: 11/688,727

(22) Filed: Mar. 20, 2007

(30) Foreign Application Priority Data
May 22, 2006 (KR) 10-2006-0045579

(51) Int. Cl. B32B 9/00; H01L 21/00

(52) U.S. Cl. 438/29; 257/E51.019; 428/690

(57) ABSTRACT

An organic light emitting diode (OLED) display includes a substrate, a first electrode disposed on the substrate, a second electrode facing the first electrode, an emission layer disposed between the first electrode and the second electrode, and a hole transport layer disposed between the first electrode and the emission layer. The hole transport layer includes a first hole transport layer comprised of a first material, a second hole transport layer comprised of a combination of the first material and a second material, and a third hole transport layer comprised of the first material. The second material has a different band gap energy from that of the first material, and the second hole transport layer and the third hole transport layer are alternately and repeatedly disposed.

### CROSS-REFERENCE TO RELATED APPLICATION

This application claims priority to and the benefit of Korean Patent Application No. 10-2006-0045579 filed in the Korean Intellectual Property Office on May 22, 2006, the contents of which are incorporated herein by reference.

### FIELD OF THE INVENTION

The present invention relates to an organic light emitting diode (OLED) display and a manufacturing method thereof.

### DESCRIPTION OF THE RELATED ART

Recently there has been a demand for lighter and slimmer monitors and televisions, so that cathode ray tubes (CRTs) have been replaced with liquid crystal displays (LCDs). Although liquid crystal displays require a backlight and they have a limited response speed and viewing angle. Organic light emitting diode (OLED) displays have been developed in order to overcome the shortcomings of liquid crystal displays. In OLED displays, an electron injected from one electrode and a hole injected from the other electrode combine at an emission layer located between the two electrodes and generate an exciton, which is illuminated while emitting energy. Because OLED displays are light-emitting display devices, they require no light source and have low power consumption.

For lower power consumption, OLED displays have to have high emission efficiency which is proportional to the number of excitons generated in the emission layer. Thus, it is necessary to balance the transferring of the electrons and holes to the emission layer.

However the mobility of holes is faster than the mobility of electrons, so it is necessary to control the mobility of the holes. A hole blocking layer may be inserted between the electrode and the emission layer. In this case, the thickness of an organic material layer is increased, and current density with respect to operating voltage is decreased. As a result, color stability depending on the current density is lowered.

### SUMMARY OF THE INVENTION

An OLED display according to an exemplary embodiment of the present invention includes a substrate, a first electrode disposed on the substrate, a second electrode facing the first electrode, an emission layer disposed between the first electrode and the second electrode, and a hole transport layer disposed between the first electrode and the emission layer. The hole transport layer includes a first hole transport layer comprised of a first material, a second hole transport layer comprised of a combination of the first material and a second material wherein the second material has a band gap energy that is different from the band gap energy of the first material, and a third hole transport layer comprised of the first material. The second and third hole transport layer are disposed alternately and repeatedly. The difference between the band gap energy of the first and second materials may be in a range of about 1 to 30% while the band gap energy of the second material may be about 1 to 30% less than the band gap energy of the first material.

The first material may be include at least one selected from the group consisting of NPB (N,N′-bis-(1-naphtyl)-N,N′-diphenyl-1,1′-biphenyl-4,4′-diamine), TPD (N,N′-diphenyl-N,N′-bis(3-methylphenyl)-1,1′-biphenyl-4,4′-diamine), PPD (p-phenylenediamine), phthalocyanine, CuPc, m-MTDATA, TPTE, polyaniline, and polythiophene.

The second material may be include at least one selected from the group consisting of rubrene, quinacridone, perylene, coumarin, DPT, PMDFB, DCJT, DCM, ABTX, BTX, PMDFB, and PtOEP.

As an example, the first material includes NPB and the second material includes rubrene. The second hole transport layer, as an example, has a combination of the first and second materials at a ratio of about 1:1.

The second hole transport layer, as an example, has a combination of the first and second materials at a ratio of about 90:10 to 10:90.

The second hole transport layer and the third hole transport layer are alternately and repeatedly disposed, as an example, three times to six times.

The OLED display may further include an electron injecting layer formed between the second electrode and the emission layer.

The OLED display may further include first and second signal lines intersecting each other and disposed between the substrate and the first electrode, a first thin film transistor connected to the first and second signal lines, and a second thin film transistor connected to the first thin film transistor and the first electrode.

A method for manufacturing an OLED display according to an exemplary embodiment of the present invention includes forming a first electrode on a substrate, forming a first hole transport layer on the first electrode, forming a second hole transport layer on the first hole transport layer wherein the second hole transport layer has a combination of two materials having different band gap energy from each other, forming a third hole transport layer on the second hole transport layer, alternately and repeatedly disposing the second hole transport layer and the third hole transport layer, and forming a second electrode on the third hole transport layer.

The first hole transport layer and the third hole transport layer may be formed from the same material.

### BRIEF DESCRIPTION OF THE DRAWINGS

The foregoing and other objects and features of the present invention may become more apparent from a reading of the ensuing description together with the drawing, in which:

FIG. 1 is a top plan view of a passive matrix OLED display according to an exemplary embodiment of the present invention;

FIG. 2 is a cross-sectional view of the OLED display illustrated in FIG. 1 taken along a line 11-11;

FIG. 3 is a schematic diagram illustrating an energy level of each layer of an OLED display according to an exemplary embodiment of the present invention;

FIG. 4 is a graph illustrating current density and luminance characteristics of OLED displays according to examples and comparative examples of the present invention;

FIG. 5 is a graph illustrating emission efficiency to current density of OLED displays according to examples and comparative examples of the present invention;

FIG. 6 and FIG. 7 are graphs each illustrating color characteristics of OLED displays according to examples and comparative examples of the present invention;

FIG. 8 is an equivalent circuit diagram of an OLED according to an exemplary embodiment of the present invention,

FIG. 9 is a layout view of an active matrix OLED display according to another exemplary embodiment of the present invention;

FIG. 10 is a cross-sectional view of the OLED display illustrated in FIG. 9 taken along a line XX-XX; and

FIG. 11 is an enlarged diagram of the “A” portion of the OLED display illustrated in FIG. 10.

### DETAILED DESCRIPTION OF THE EMBODIMENTS

In the drawings, the thicknesses of layers, films, panels, regions, etc., are exaggerated for clarity. It will be understood that when an element such as a layer, film, region, or substrate is referred to as being “on” another element, it can be directly on the other element or intervening elements may also be present. In contrast, when an element is referred to as being “directly on” another element, there are no intervening elements present.

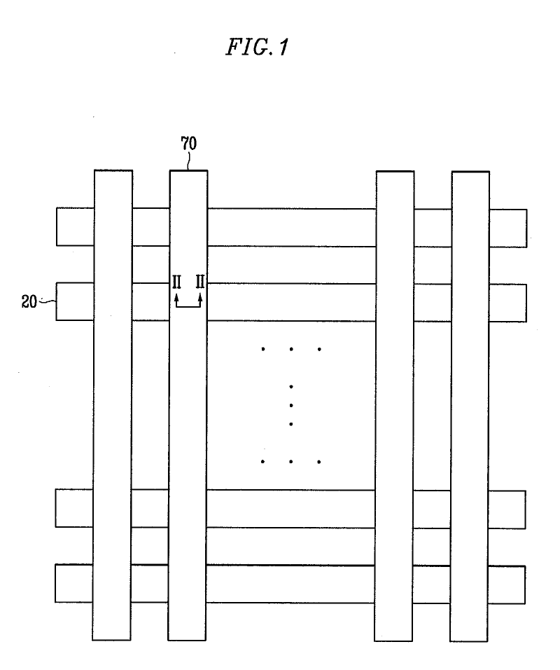

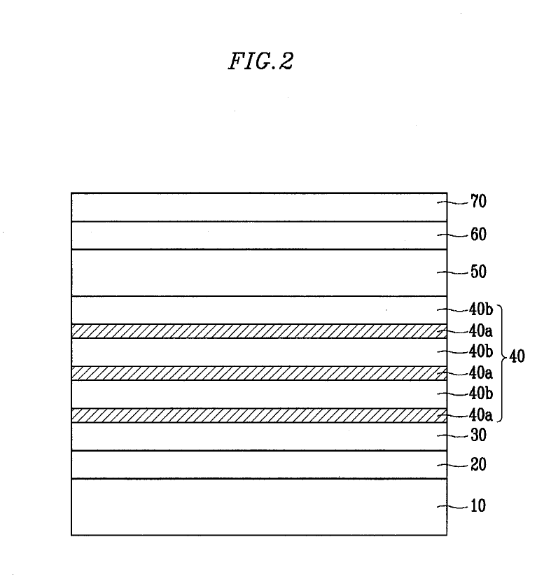

FIG. 1 is a top plan view of a passive matrix OLED display according to an exemplary embodiment of the present invention, and FIG. 2 is a cross-sectional view of the OLED display illustrated in FIG. 1 taken along a line 11-11. A plurality of anodes 20 and a plurality of cathodes 70 are formed on an insulating substrate 10 formed of transparent glass or plastic.

Anodes 20 are formed with a space therebetween and extend in one direction of insulating substrate 10. Anodes 20 are electrodes in which holes are injected and may be made of a transparent conductive material having a high work function which emit light. The conductive material includes, for example, indium tin oxide (ITO) or indium zinc oxide (IZO).

Cathodes 70 are formed at predetermined intervals on substrate 10, and extend in the other direction to anodes 20. Cathodes 70 are electrodes in which electrons are injected, and may be made of a conductive material having a low work function that include, for example, aluminum (Al), calcium (Ca), or barium (Ba). An organic light emitting member is formed between anodes 20 and cathodes 70. The organic light emitting member includes an emission layer 50 and a plurality of auxiliary layers to increase the emission efficiency of emission layer 50.

Emission layer 50 may be made of an organic material, a non-organic material, or a mixture thereof that emits one of the primary colors, such as red, green, or blue. Emission layer 50 includes, for example, aluminum tris(8-hydroxyquinoline) (Alq3), anthracene, a distryl compound, a polyfluorene derivative, a (poly)paraphenylenevinylene derivative, a polyphenylene derivative, polyvinylcarbazole, a polythiophene derivative, or a high molecular compound thereof doped with a perylene type of pigment, a cumarine type of pigment, a rhodamine type of pigment, rubrene, perylene, 9,10-diphenylanthracene, tetraphenylbutadiene, Nile red, coumarin, or quinacridone. The OLED display forms desired images with a dimensional sum of the primary colors emitted from the emission layer.

As auxiliary layers, there are hole transport layers 30 and 40 and an electron transport layer 60 to balance the electrons and the holes.

Hole transport layers 30 and 40 are disposed between anode 20 and emission layer 50, and include a lower hole transport layer 30 and an upper hole transport layer 40. The lower hole transport layer 30 is a monolayer, and the upper hole transport layer 40 is a multilayer.

The lower hole transport layer 30 allows the holes to be easily transported from anode 20 to emission layer 50. Lower hole transport layer 30 is made of a material having a value that is the highest occupied molecular orbital (“HOMO”) level between the work function of anode 20 and that of emission layer 50. For example, the material includes at least one selected from the group consisting of N,N′-bis-(1-naphtyl)-N,N′-diphenyl-1,1′-biphenyl-4,4′-diamine (NPB), N,N′-diphenyl-N,N′-bis(3-methylphenyl)-1,1′-biphenyl-4,4′-diamine (TPD), p-phenylenediamine (PPD), phthalocyanine, CuPc, m-MTDATA, polyaniline, and polythiophene.

Upper hole transport layer 40 includes a first upper hole transport layer 40a and a second upper hole transport layer 40b. The first upper hole transport layer 40a is made of a combination of two materials each having different band gap energy, and the second upper hole transport layer 40b is made of a single material.

The first upper hole transport layer 40a is made of a combination of a first material and a second material. The first material has a HOMO level having a value between the values of the work functions of anode 20 and HOMO level of emission layer 50. The second material has a band gap energy that is greater or less than the band gap energy of the first material. For example, the band gap energy difference between the first material and the second material is in the range of about 1 to 30%.

The first material includes at least one material among the materials stated above so as to facilitate hole transport. The second material includes at least one selected from the group consisting of rubrene, quinacridone, perylene, coumarin, DPT, PMDFB, DCJT, DCM, ABTX, BTX, PMDFB, and PtOEP. The second material is an impurity (dopant). Because the second material has a different energy level from HOMO level of the first material, it forms an energy barrier for hole transport and lowers the mobility of the holes. The second upper hole transport layer 40b is made only of the first material for hole transport.

The first upper hole transport layer 40a and the second upper hole transport layer 40b are alternately and repeatedly disposed, for example three times to six times.

The electron transport layer 60 is disposed between emission layer 50 and cathode 70, and includes, for example, lithium fluoride (LiF), lithium quinolate (Liq), oxadiazole, triazole, or triazine.

In addition to the hole transport layers 30 and 40 and the electron transport layer 60, the OLED display may further include one or two auxiliary layers, such as an electron injection layer (not shown) or a hole injection layer (not shown) for enforcing the injection of the electrons or holes.

According to an exemplary embodiment of the present invention, as described above, the mobility of hole transport from anode 20 to emission layer 50 is appropriately controlled by alternately and repeatedly disposing the first upper hole transport layer 40a made of a combination of materials having different energy levels and the second upper hole transport layer 40b made of a single material.

Referring to FIGS. 1-3, the control of the hole mobility is described in detail.

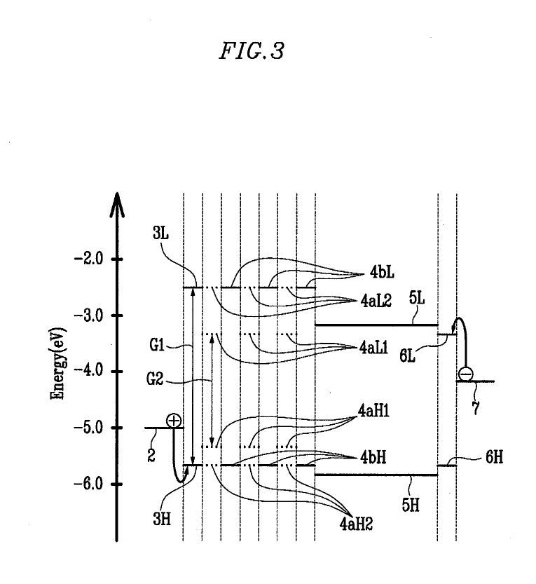

FIG. 3 is a schematic diagram illustrating an energy level of each layer of an OLED display according to an exemplary embodiment of the present invention.

In FIG. 3, the vertical axis represents energy levels in the units of eV, and the horizontal axis represents, in a direction from left to right, the energy level (work function) 2 of anode 20, HOMO level 3H and LUMO level3L of the lower hole transport layer 30, HOMO level 4aH2 and LUMO level 4aL2 of the first material of the first upper hole transport layer 40a, HOMO level 4aH1 and LUMO level 4aL1 of the second material of the first upper hole transport layer 40a, HOMO level 4bH and LUMO level 4bL of the second upper hole transport layer 40b, HOMO level 5H and LUMO level 5L of emission layer 50, HOMO level 6H and LUMO level 6L of the electron transport layer 60, and the energy level (work function) 7 of cathode 70, respectively.

The transport of the holes injected through anode 20 will now be explained.

Some of the holes injected from anode 20 having a work function 2 of about −5.0 eV pass through HOMO level 3H of lower hole transport layer 30. Then the holes pass through HOMO level 4aH1 of the second material of the first upper hole transport layer 40a and HOMO level 4bH of the second upper hole transport layer 40b several times, and arrive at HOMO level 5H of emission layer 50. In this case, the mobility of the holes is lowered because the energy difference between HOMO level 4aH1 of the second material of the first upper hole transport layer 40a and HOMO level 4bH of the second upper hole transport layer 40b acts as a barrier.

In order to appropriately control the energy barrier, the band gap energy G2 of the second material is, for example, about 1 to 30% less than the band gap energy G1 of the first material. When the band gap energy difference is lower than about 1%, the energy barrier is rarely formed. When the band gap energy difference is higher than about 30%, the hole mobility is too low so that the number of holes transported to the emission layer is significantly deceased.

The rest of the holes injected from anode 20 having a work function of about −5.0 eV pass through HOMO level 3H of the lower hole transport layer 30. Then the holes pass through HOMO level 4aH2 of the first material of the first upper hole transport layer 40a and HOMO level 4bH of the second upper hole transport layer 40b several times and arrive at HOMO level 5H of emission layer 50. In this case, the hole mobility is not affected because there is no energy difference between HOMO level 4aH2 of the first material of the first upper hole transport layer 40a and HOMO level 4bH of the second upper hole transport layer 40b.

The transport of the electrons injected through cathode 70 takes place as follows. The electrons injected from cathode 70 having work function 7 of about −4.2 to −4.3 eV arrive at LUMO level SL of emission layer 50 after passing through LUMO level 6L of electron transport layer 60.

On emission layer 50, the holes having HOMO level 5H and the electrons having LUMO level 5L are recombined to generate excitons, which emit light while losing energy.

As described above, the transport of holes injected from anode 20 traverses a first passage, that is, 2/3H/4aH1/4bH/4aH1/4bH/4aH1/4bH/5H, in which the holes are transported along the energy barrier formed by the energy difference of the hole transport layers, and a second passage, that is, 2/3H/4aH2/4bH/4aH2/4bH/4aH2/4bH/5H, in which the holes are transported without the energy difference of the hole transport layers. In the first passage the energy barrier lowers hole mobility while, in the second passage, hole mobility is maintained.

The ratio of the holes transported through the first passage to the holes transported through the second passage is determined by the combination ratio of the first and second materials. Preferably, the combination ratio of the first material to the second material is in a range of about 90:10 to 10:90. More preferably, the combination ratio of the first material to the second material is about 1:1.

Thus, the OLED display according to an exemplary embodiment of the present invention can lower the hole mobility and balance the transport of the holes and electrons to the emission layer, in comparison with the OLED in which only a single hole transport layer is inserted between anode 20 and emission layer 50. Accordingly, the OLED display according to an exemplary 20 embodiment of the present invention improves emission efficiency by increasing a recombination ratio between the holes and the electrons at the emission layer.

Further, the OLED display according to an exemplary embodiment of the present invention can prevent degradation of current characteristics due to trapping of the holes in a single impurity layer. Further, color purity is maintained and stability increased due to the peak related to exciplexes, in comparison with the OLED in which the single impurity layer, rather than a combination layer, is disposed between anode 20 and emission layer 50.

The current characteristic, emission efficiency, color purity, and color stability of the OLED displays according to an exemplary embodiment of the present invention and the OLED displays according to comparative examples are determined as follows.

### EXAMPLE

According to an exemplary embodiment of the present invention, the OLED display illustrated in FIG. 1 and FIG. 2 is manufactured. An anode 20 was formed on an insulating substrate 10 by sputtering a transparent conductor such as ITO on the insulating substrate 10. Then, substrate 10 was placed in a chamber filled with acetone or isopropyl alcohol. Ultrasonic wave cleaning and oxygen plasma treatment were performed to improve the interface characteristic of anode 20.

NPB was vacuum-deposited on anode 20 to a thickness of about 10 nm to form a lower hole transport layer 30. A mixture in which NPB and rubrene were mixed in a ratio of about 1:1 was deposited to a thickness of about 3 nm on the lower hole transport layer 30 to form a first upper hole transport layer 40a. NPB was deposited to a thickness of about 3 nm on the first upper hole transport layer 40a to form a second upper hole transport layer 40b. The first upper hole transport layer 40a and the second upper hole transport layer 40b were deposited three times to form a plurality of upper hole transport layers 40. Alq3 was deposited on the upper hole transport layer 40 to form an emission layer 50, and Liq was deposited to form an electron transport layer 60.

Finally, aluminum was deposited on the electron transport layer 60 to form a cathode 70. As a result, an OLED display in which ITO, NPB, [(NPB: rubrene)/NPB]₃, Alq3, Liq, and Al were sequentially deposited is manufactured.

### Comparative Example 1

An OLED display according to Comparative Example 1 does not have the upper hole transport layer 40, in comparison with the OLED display according to the Example. Thus, ITO, NPB, Alq3, Liq, and Al were sequentially deposited on a substrate to manufacture an OLED display.

### Comparative Example 2

The OLED according to Comparative Example 2 has a structure in which a single impurity layer made of rubrene and a hole transport layer made of NPB as hole transport layers were alternately and repeatedly deposited, in comparison with the OLED according to the Example. Thus, ITO, NPB, (rubrene/NPB)₃, Alq3, Liq, and Al were sequentially deposited on a substrate to manufacture an OLED display.

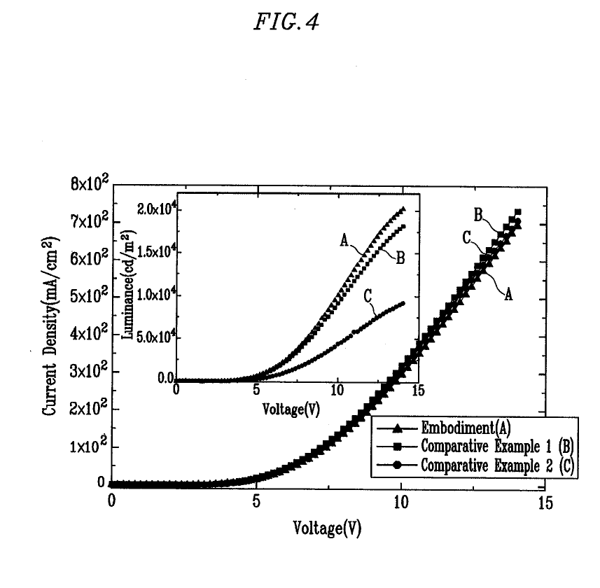

Hereinafter, referring to FIGS. 4 to 7, the current characteristic, emission efficiency, color purity, and color stability of the OLED displays according to the Example and Comparative Examples 1 and 2 are illustrated.

Referring to FIG. 4, current density and luminance measurement results are described.

FIG. 4 is a graph illustrating current density and luminance characteristics of the OLED displays according to the Example and the Comparative Examples 1 and 2.

The current densities of the OLED display according to the Example (hereinafter “display A”) and the OLED displays according to Comparative Examples 1 and 2 (hereinafter “displays B and C”) are measured with a KEITHLEY device (model: 236 SOURCE-MEASURE UNIT). Voltages between 0 to 15V are applied to the displays in steps of 0.5V.

As shown in FIG. 4, each of turn-on voltages of displays A, B, and C is about 3.5V, and each display has similar current density to voltage characteristics. In comparison with display B, displays A and C include combination layers or single impurity layers between an anode and an emission layer so that hole mobility is lowered and the current density to voltage is somewhat low. But the difference of the current density to voltage characteristics between the displays is not large.

The displays A, B, and C are placed in a black box, and the luminance of the displays is measured with a KEITHLEY device (model: 236 SOURCE-MEASURE UNIT). A voltage between 0 to 15V is applied to the displays in steps of 0.5V.

As shown in FIG. 4, at the same voltage, the luminance of the display A has the highest value. This is because the display A according to the Example of the present invention controls hole mobility so that the balance of the holes and electrons at an emission layer is maximized.

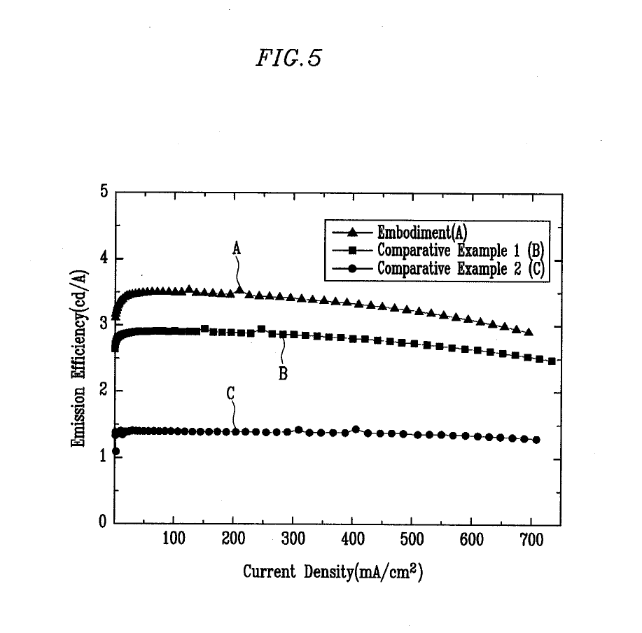

Referring to FIG. 5, the emission efficiency to current density is illustrated for the OLED displays according to the Example and Comparative Examples.

Based on the current density shown in FIG. 4, the emission efficiency to current density is determined. At a current density greater than about 100 mA/□, the display A has emission efficiency of about 3.0 to 3.5 cd/A, the display B has emission efficiency of about 2.5 to 3 cd/A, and the display C has emission efficiency of about 1 to 1.5 cd/A.

Therefore, display A according to the Example of the present invention has greater current efficiency than that of display B having a hole transport layer with no energy barrier and that of the display C having a single impurity layer.

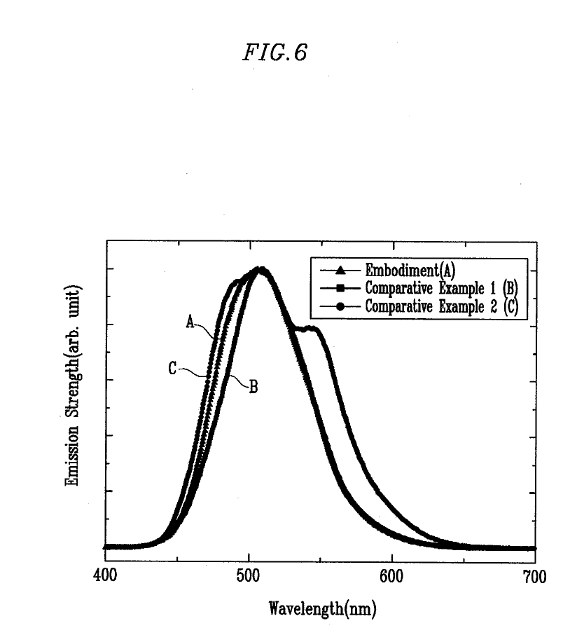

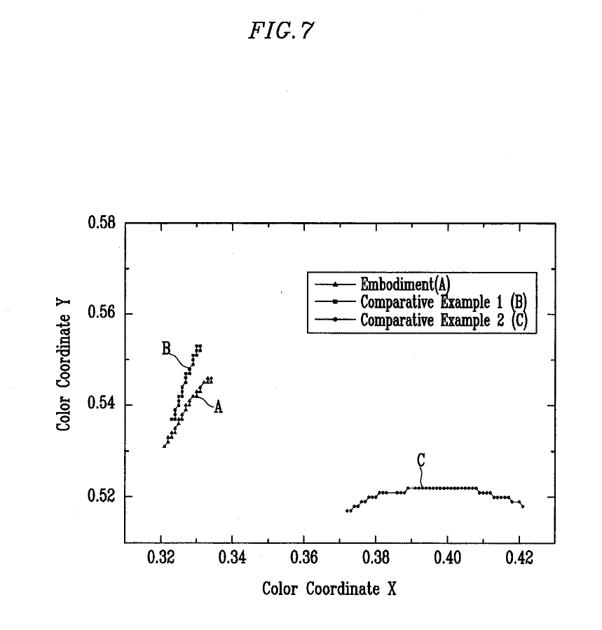

Referring to FIG. 6 and FIG. 7, the color characteristic of the OLED display is illustrated.

FIG. 6 and FIG. 7 are graphs each illustrating the color characteristics of the OLED displays according to the Example and Comparative Examples 1 and 2.

The graph illustrated in FIG. 6 is the emission strength to wavelength measured by applying a voltage of about 11 V to the displays A, B, and C. Within a narrow wavelength range, the color purity is high when the emission strength is high. As shown in FIG. 6, display A shows the strongest emission at a wavelength of about 500 nm. Thus, display A has emission within a narrower wavelength range, in comparison with display C. In contrast, display C has emission over a broad wavelength range, because holes are trapped in the single impurity layer, and an unnecessary peak due to exciplexes that are generated.

FIG. 7 is a graph illustrating color coordinates measured while changing voltages applied to displays A, B, and C. Color stability is high when the change of color coordinates is small in response to the change of voltage. Display A has higher color stability than that of display C.

Still referring to FIG. 4 to FIG. 7, the OLED display according to the Example of the present invention has similar current density to those of the OLED displays of the Comparative Examples, while the OLED display according to the Example of the present invention has greater luminance, emission efficiency, color purity, and color stability than those of the OLED displays according to the Comparative Examples.

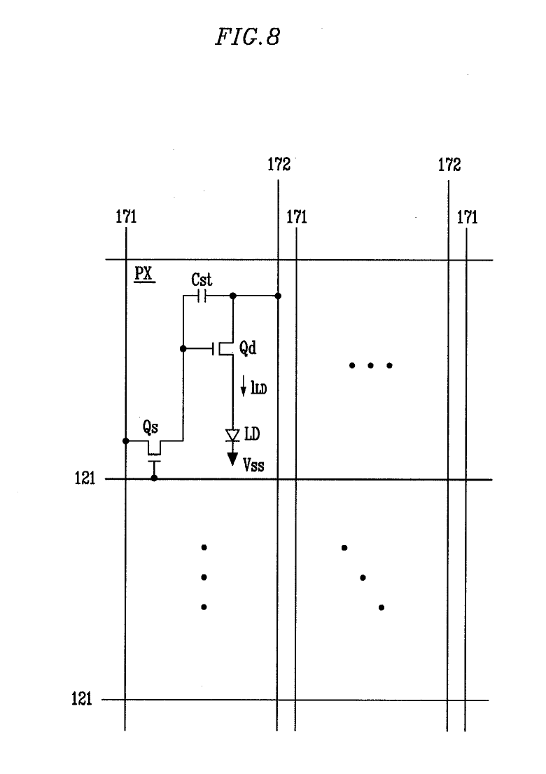

Referring to FIGS. 8 to 11, an OLED display according to another exemplary embodiment of the present invention is illustrated. The OLED display is an active matrix OLED display. Duplicate descriptions are omitted. FIG. 8 is an equivalent circuit diagram of an OLED display according to an exemplary embodiment of the present invention.

Referring to FIG. 8, the OLED display according to the present exemplary embodiment includes a plurality of signal lines 121, 171, and 172, and a plurality of pixels connected to the signal lines 121, 171, and 172 and arranged in a matrix.

The signal lines include a plurality of gate lines 121 for transferring gate signals (or scanning signal), a plurality of data lines 171 for transferring data signals, and a plurality of driving voltage lines 172 for transferring driving voltages. The gate lines 121 extend in a row direction and parallel to each other. The data lines 171 and the driving voltage lines 172 extend in a column direction and are parallel to each other.

Each pixel PX includes a switching transistor Qs, a driving transistor Qd, a storage capacitor Cst, and an organic light emitting diode (OLED) LD.

The switching transistor Qs includes a control terminal, an input terminal, and an output terminal. The control terminal is connected to a gate line 121, the input terminal is connected to a data line 171, and the output terminal is connected to a driving transistor Qd. The switching transistor Qs transfers the data signal to be applied to the data line 171 to the driving transistor Qd, in response to a scanning signal applied to the gate line 121.

Driving transistor Qd includes a control terminal, an input terminal, and an output terminal. The control terminal is connected to the switching transistor Qs, the input terminal is connected to a driving voltage line 172, and the output terminal is connected to the OLED LD. The driving transistor Qd outputs an output current ILD depending on the voltage applied between the control terminal and the output terminal.

Capacitor Cst is connected between the control terminal and the input terminal of driving transistor Qd. Capacitor Cst charges the data signal to be applied to the control terminal of driving transistor Qd and maintains the charged data signal after switching transistor Qs is turned off.

The OLED LD includes an anode connected to the output terminal of driving transistor Qd and a cathode connected to a common voltage Vss. The OLED LD emits light whose strength changes depending on the output current ILD of diving transistor Qd, thereby displaying images.

Switching transistor Qs and driving transistor Qd are n-channel electric field effect transistors (FETs). At least one of the switching transistor Qs and the driving transistor Qd may be a p-channel electric field effect transistor. The connections of the transistors Qs and Qd, the capacitor Cst and the OLED LD may be changed.

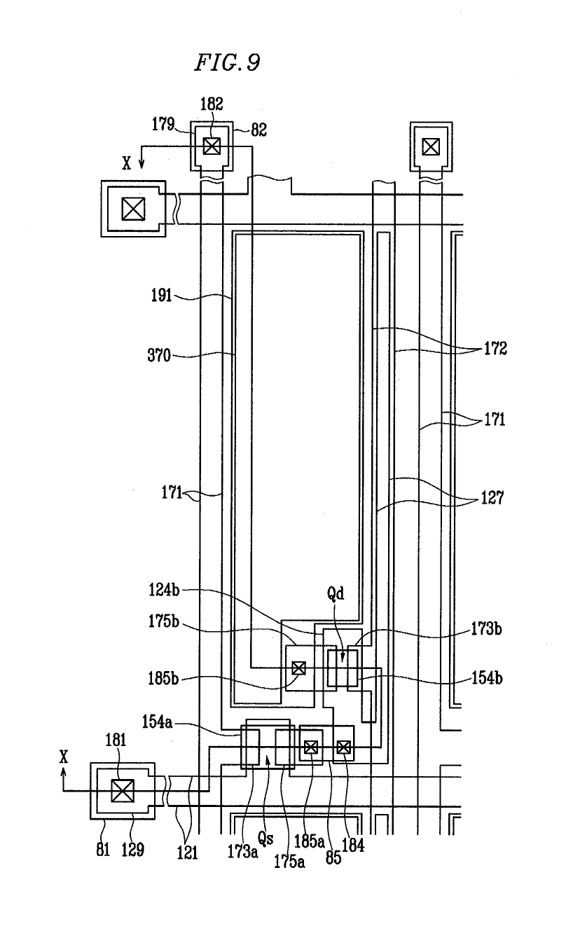

Referring to FIGS. 9-11, the OLED display illustrated in FIG. 8 is illustrated in detail.

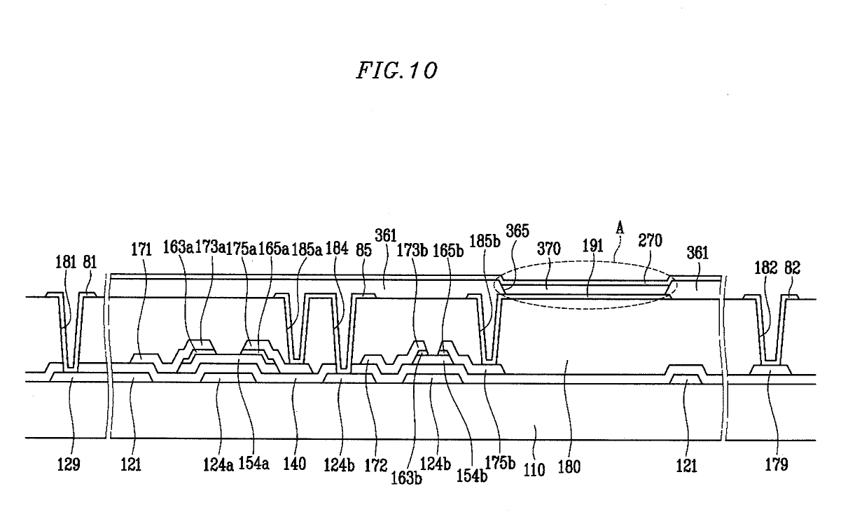

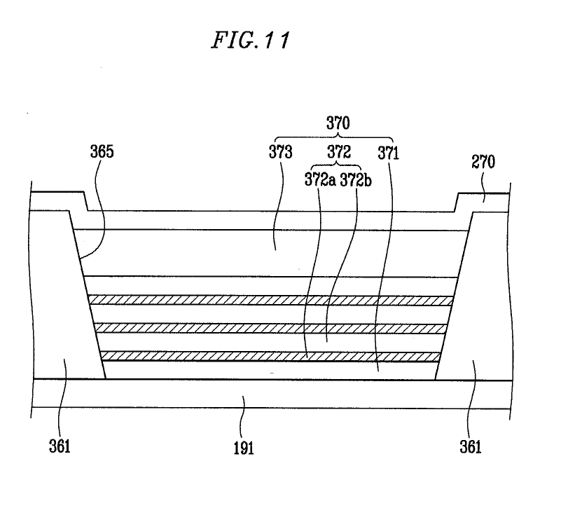

FIG. 9 is a layout view of an OLED display according to another exemplary embodiment of the present invention, FIG. 10 is a cross-sectional view of the OLED display of FIG. 9 taken along a line X-X, and FIG. 11 is an enlarged view of the portion “A” of the OLED display illustrated in FIG. 10.

On an insulating substrate 110, a plurality of gate conductors including a plurality of gate lines 121 having first control electrodes 124a and second control electrodes 124b are formed. Each second control electrode 124b has a storage electrode 127.

Gate lines 121 transfer gate signals and extend in a horizontal direction. Each gate line 121 has an end portion 129 having a large area for connection to another layer or an external driving circuit. The first control electrode 124a extends upward from the gate line 121. In the case that a gate driving circuit (not shown) for generating a gate signal is integrated on the substrate 110, the gate line 121 may extend and directly connect to the gate driving circuit.

The second control electrode 124b is spaced apart from gate line 121, and includes storage electrode 127 extended in a predetermined direction.

Gate conductors 121 and 124b may be made of, for example, an aluminum-containing metal such as aluminum (Al) or an aluminum alloy, a silver-containing metal such as silver (Ag) or a silver alloy, a copper-containing metal such as copper (Cu) or a copper alloy, a molybdenum-containing metal such as molybdenum (Mo) or a molybdenum alloy, chromium (Cr), tantalum (Ta), or titanium (Ti). The gate conductors 121 and 124b may have a multilayered structure having two conductive layer (not shown) having different physical properties.

The side surfaces of gate conductors 121 and 124b are inclined to the surface of the substrate 110. For example, the angle between the side surfaces of the gate conductors 121 and 124b and the surface of the substrate 110 is about 30° to about 80°.

A gate insulating layer 140 made of silicon nitride or silicon oxide is formed on the gate conductors 121 and 124b.

A plurality of semiconductor islands 154a and 154b, which are made of hydrogenated amorphous silicon (abbreviated to a-Si) or polycrystalline silicon, are formed on the gate insulating layer 140. The first semiconductor island 154a and the second semiconductor island 154b are located on the first control electrode 124a and the second control electrode 124b, respectively.

A plurality of pairs of first ohmic contact members 163a and 165a and a plurality of pairs of second ohmic contact members 163b and 165b are formed on the first semiconductor island 154a and the second semiconductor island 154b, respectively. The ohmic contact members 163a, 163b, 165a, and 165b have an island shape, and are made of an n+ hydrogenated amorphous silicon material in which an n-type impurity such as phosphorus (P) is doped in a high concentration, or silicide. The first ohmic contact members 163a and 165a form a pair, which is disposed on the first semiconductor island 154a. The second ohmic contact members 163b and 165b also form a pair, which is disposed on the second semiconductor island 154b.

On the ohmic contact members 163a, 163b, 165a, and 165b and the gate insulating layer 140, a plurality of data conductors having a plurality of data lines 171, a plurality of driving voltage lines 172, and a plurality of first and second output electrodes 175a and 175b, are formed.

Data lines 171 transfer data signals and extend in a vertical direction to intersect the gate lines 121. Each of the data lines 171 has a plurality of first input electrodes 173a extending toward the first control electrode 124a, and an end portion 179 having a large area for connecting to another layer or an external driving circuit. In the case that a data driving circuit (not shown) for generating data signals is integrated on the substrate 110, the data lines 171 may extend and directly connect to the data driving circuit.

Driving voltage lines 172 transfer driving voltages and extend in a vertical direction to intersect the gate lines 121. Each of the driving voltage lines 172 has a plurality of second input electrodes 173b extending toward the second control electrode 124b, and a portion overlapped with the storage electrode 127.

The first and second output electrodes 175a and 175b are separated from each other and are also separated from data lines 171 and driving voltage lines 172. The first input electrode 173a and the first output electrode 175a face each other on the first semiconductor island 154a, while the second input electrode 173b and the second output electrode 175b face each other on the second semiconductor island 154b.

Particularly, the data conductors 171, 172, 175a, and 175b may be made of a heat resistant metal such as molybdenum, chromium, tantalum, or titanium, or an alloy thereof. The data conductors may have a multilayered structure having a heat resistant metal layer (not shown) and a low resistance conductive layer (not shown).

As in the gate conductors 121 and 124b, the side surfaces of the data conductors 171, 172, 175a, and 175b are inclined to the surface of the substrate 110. Particularly, the angle between the side surfaces of the data conductors and the surface of the substrate is about 30° to 80°.

The ohmic contact members 163a, 163b, 165a, and 165b are formed only between the semiconductor islands 154a and 154b disposed under the ohmic contact members and the data conductors 171, 172, 175a, and 175b disposed on the ohmic contact members to lower contact resistance therebetween. The semiconductor islands 154a and 154b have an exposed portion, such as a portion between the input electrodes 173a and 173b and the output electrodes 175a and 175b, or a portion that is not covered by the data conductors 171, 172, 175a, and 175b.

A passivation layer, 80 is formed on both the data conductors 171, 172, 175a, and 175b and the exposed portions of the semiconductor islands 154a and 154b. The passivation layer 180 may be made of an inorganic insulating material or an organic insulating material, and has an even surface. As examples of the inorganic insulating material, there are silicon nitride and silicon oxide. The organic insulating material has photosensitivity and a dielectric constant of, for example, less than about 4.0. The passivation layer 180 may have a double-layer structure of an upper organic layer and a lower inorganic layer in order to maintain excellent insulating characteristics of the organic layer while preventing the exposed portions of the semiconductors 151 and 154b from being damaged.

A plurality of contact holes 182, 185a, and 185b, each exposing the end portions 179 of the data lines 171 and the first and the second output electrodes 175a and 175b, are formed in the passivation layer 180. A plurality of contact holes 181 and 184, each exposing the end portions 129 of the gate lines 121 and the second input electrodes 124b, are formed in the passivation layer 180 and the gate insulating layer 140.

A plurality of pixel electrodes 191, a plurality of connecting members 85, and a plurality of contact assists 81 and 82 are formed on the passivation layer 180. They may be made of a transparent conductive material such as ITO or IZO, or a reflective metal such as aluminum, silver, or alloys thereof.

Each pixel electrode 191 is physically and electrically connected to a second output electrode 175b through a contact hole 185b.

Each connecting member 85 is connected to a second control electrode 124b and a first output electrode 175a through the contact holes 184 and 185a.

The contact assists 81 and 82 are connected to the end portions 129 of the gate lines 121 and the end portions 179 of the data lines 171 through the contact holes 181 and 182, respectively. The contact assists 81 and 82 improve the connectivity between the end portions 129 and 179 of the gate lines 121 and data lines 171 and an external device, and protect the end portions.

Partitions 361 are formed on the passivation layer 180. The partitions 361 surround an edge of each pixel electrode 191 to define an opening 365, and may be made of an organic insulating material or an inorganic insulating material. The partitions 361 may be made of a photosensitive material having a black pigment. In this case, the partitions 361 act as a light blocking member and are easily formed.

An organic emission member 370 is formed in the opening 365.

The organic emission member 370 has a plurality of auxiliary layers 371 and 372 in order to improve the emission efficiency of an emission layer 373.

Emission layer 373 may be made of a high molecular compound, such as a polyfluorene derivative, a (poly)paraphenylene vinylene derivative, a polyphenylene derivative, polyvinylcarbozol, or a polythiophene derivative, and formed by inkjet printing.

As the auxiliary layers, there are hole transport layers 371 and 372 and an electron transport layer (not shown). The hole transport layers 371 and 372, as described with respect to the above exemplary embodiment, include a lower monolayer hole transport layer 371 and an upper multilayer hole transport layer 372.

The lower hole transport layer 371 allows the holes to be easily transported from the pixel electrode 191 to the emission layer 373, and is made of a material having a HOMO level of which value is between the values of the work functions of the pixel electrode 191 and HOMO levels of the emission layer 373.

The upper hole transport layer 372 includes a first upper hole transport layer 372a having a combination of two materials with different band gap energy and a second upper hole transport layer 372b of a single material.

The first upper hole transport layer 372a has a first material having a HOMO level of which value is between the values of the work functions of the pixel electrode 191 and HOMO level of the emission layer 373, and a second material having an band gap energy that is greater or less than the band gap energy of the first material. For example, the band gap energy difference between the first material and the second material is about 1 to 30%.

The second upper hole transport layer 372b is made of only the first material for hole transfer.

The first upper hole transport layer 372a and the second upper hole transport layer 372b are alternately and repeatedly disposed, for example three to six times.

According to an exemplary embodiment of the present invention, the first upper hole transport layer 372b on which two materials having different energy levels are combined and the second upper hole transport layer 372b having a single material are alternately disposed, so that the mobility of holes transported from the pixel electrode 191 to the emission layer 373 is appropriately controlled.

A common electrode 270 is formed on the organic emission member 370.

An encapsulation layer (not shown) may be formed on the common electrode 270. The encapsulation layer encapsulates the organic emission member 370 and the common electrode 270, and prevents moisture and/or oxygen from permeating therein from the outside.

In the OLED display, the first control electrode 124a connected to the gate line 121, the first input electrode 173a and first output electrode 175a connected to the data line 171, and the first semiconductor island 154a form a switching thin film transistor Qs. The switching thin film transistor Qs has a channel formed in the first semiconductor island 154a between the first input electrode 173a and the first output electrode 175a. The second control electrode 124b connected to the first output electrode 175a, the second input electrode 173b connected to the driving voltage line 172, the second output electrode 175b connected to the pixel electrode 191, and the second semiconductor island 154b form a driving thin film transistor Qd. The driving thin film transistor Qd has a channel formed in the semiconductor island 154b between the second input electrode 173b and the second output electrode 175b. In order to increase the driving current, either the channel width of the driving thin film transistor Qd is increased or the channel length of the transistor is shortened.

A pixel electrode 191, the organic emission member 370, and the common electrode 270 form an organic light emitting diode (OLED) LD. The pixel electrode acts as an anode and the common electrode 270 acts as a cathode. Alternatively, the pixel electrode 191 acts as a cathode, and the common electrode 270 acts as an anode. The storage electrode 127 and driving voltage line 172 overlapping each other form a storage capacitor Cst.

In the case that the semiconductor islands 154a and 154b are formed from polycrystalline silicon, the display includes an intrinsic region (not shown) facing the control electrodes 124a and 124b and an extrinsic region located at both ends of the intrinsic region. The extrinsic region is electrically connected to the input electrodes 173a and 173b and output electrodes 175a and 175b. In this case, the ohmic contact members 163a, 163b, 165a, and 165b may be omitted.

Alternatively, the control electrodes 124a and 124b may be formed on the semiconductor islands 154a and 154b. In this case, the gate insulating layer 140 is disposed between the semiconductor islands 154a and 154b and the control electrodes 124a and 124b. The data conductors 171, 172, 173b, and 175b are disposed on the gate insulating layer 140 and electrically connected to the semiconductor islands 154a and 154b through a contact hole (not shown) on the gate insulating layer 140. Alternatively, the data conductors 171, 172, 173b, and 175b may be disposed under the semiconductor islands 154a and 154b and be electrically connected to the semiconductor islands 154a and 154b.

According to an exemplary embodiment of the present invention, an OLED display improves luminance, emission efficiency, color purity, and color stability by controlling the mobility of holes transporting from an electrode to an emission layer.

While this invention has been described in connection with what is presently considered to be practical exemplary embodiments, it is to be understood that various modifications and equivalent arrangements will be apparent to those skilled in the art and may be made without, however, departing from the spirit and scope of the invention.

What is claimed is:

1. An organic light emitting diode (OLED) display comprising:
a substrate;
a first electrode disposed on the substrate;
a second electrode facing the first electrode;
an emission layer disposed between the first electrode and the second electrode; and
a hole transport layer disposed between the first electrode and the emission layer,
wherein the hole transport layer comprises:
a first hole transport layer including a first material,
a second hole transport layer including a combination of the first material and a second material wherein the second material has a different band gap energy than that of the first material, and
a third hole transport layer including the first material,
the second hole transport layer and the third hole transport layer being alternately disposed.

2. The OLED display of claim 1, wherein the difference between the band gap energy of the first and second materials is in a range of about 1 to 30%.

3. The OLED display of claim 2, wherein the band gap energy of the second material is about 1 to 30% less than the band gap energy of the first material.

4. The OLED display of claim 2, wherein the first material includes at least one selected from the group consisting of N,N′-bis-(1-naphthyl)-N,N′-diphenyl-1,1′-biphenyl-4,4′-diamine, N,N′-diphenyl-N,N′-bis(3-methylphenyl)-1,1′-biphenyl-4,4′-diamine, p-phenylenediamine, phthalocyanine, CuPc, m-MTDATA, TPTE, polyaniline, and polythiophene.

5. The OLED display of claim 4, wherein the second material includes at least one selected from the group consisting of rubrene, quinacridone, perylene, coumarin, DPT, PMDFB, DCJT, DCM, ABTX, BTX, PMDFB, and PtOEP.

6. The OLED display of claim 5, wherein the first material includes N,N′-bis-(1-naphtyl)-N,N′-diphenyl-1,1′-biphenyl-4,4′-diamine, and the second material includes rubrene.

7. The OLED display of claim 1, wherein the second hole transport layer has a combination of the first and second materials in a ratio of about 90:10 to about 10:90.

8. The OLED display of claim 7, wherein the second hole transport layer has a combination of the first and second materials in a ratio of about 1:1.

9. The OLED display of claim 1, wherein the second hole transport layer and the third hole transport layer are alternately disposed three to six times.

10. The OLED display of claim 9, further comprising an electron injecting layer formed between the second electrode and the emission layer.

11. The OLED display of claim 1, further comprising:
first and second signal lines intersecting each other and disposed between the substrate and the first electrode;
a first thin film transistor connected to the first and second signal lines; and
a second thin film transistor connected to the first thin film transistor and the first electrode.

12. A method for manufacturing an organic light emitting diode (OLED) display, comprising:
forming a first electrode on a substrate;
forming a first hole transport layer on the first electrode;
forming a second hole transport layer on the first hole transport layer, the second hole transport layer having a combination of two materials having different band gap energy from each other;
forming a third hole transport layer on the second hole transport layer;
alternately disposing the second hole transport layer and the third hole transport layer; and
forming a second electrode on the third hole transport layer.

13. The method of claim 12, wherein the first hole transport layer and the third hole transport layer are formed of the same material.
